(19) United States
(12) Patent Application Publication
(10) Pub. No.: US 2010/0012934 A1
(43) Pub. Date: Jan. 21, 2010

(54) SEMICONDUCTOR CHIP AND SEMICONDUCTOR CHIP STACKED PACKAGE

(76) Inventor: Oh-Jin Jung, Bucheon-si (KR)

Correspondence Address: SHERR & VAUGHN, PLLC, 620 HERNDON PARKWAY, SUITE 320, HERNDON, VA, 20170, US

(21) Appl. No.: 12/502,791

(22) Filed: Jul. 14, 2009

(30) Foreign Application Priority Data
Jul. 17, 2008 (KR) 10-2008-0069722

(51) Int. Cl. H01L 23/522

(52) U.S. Cl. 257/48; 257/758; 257/737; 257/E23.145

(57) ABSTRACT

A semiconductor chip in a semiconductor chip stacked package may include a semiconductor substrate formed with a semiconductor device, an insulating layer over the semiconductor substrate, a deep via passing through the semiconductor substrate and the insulating layer, an interconnection layer electrically connecting the semiconductor device with the deep via, and a test device electrically connected with both the deep via and the interconnection layer.

The present application claims priority under 35 U.S.C. 119 to Korean Patent Application No. 10-2008-0069722 (filed on Jul. 17, 2008), which is hereby incorporated by reference in its entirety.

### BACKGROUND

Recently, as portable electronic appliances have rapidly spread in the market of electronic appliances, components of the portable electronic appliances have a lightweight, small, and slim structure. In order to realize the components having the lightweight, small, and slim structure, the size of a semiconductor package that is one of the components must be reduced. In addition, an SOC (system on chip) technology, which combine a plurality of individual semiconductor chips into one chip, and an SIP (system in package) technology, which integrates a plurality of individual semiconductor chips into one package, are required.

When a plurality of individual semiconductor chips are integrated into one package, the package must have an improved physical strength, and the performance and the reliability of the chips arranged in the package must be improved.

### SUMMARY

Embodiments relate to a semiconductor chip and a semiconductor chip stacked package, in which the reliability of the semiconductor chip stacked package can be tested.

According to embodiments, a semiconductor chip may include a semiconductor substrate formed with a semiconductor device, an insulating layer over the semiconductor substrate, a deep via passing through the semiconductor substrate and the insulating layer, an interconnection layer electrically connecting the semiconductor device with the deep via, and a test device electrically connected with both the deep via and the interconnection layer.

According to embodiments, a semiconductor chip stacked package may include a first semiconductor chip, which includes a semiconductor substrate formed with a semiconductor device, an insulating layer over the semiconductor substrate, a deep via passing through the semiconductor substrate and the insulating layer, an interconnection layer electrically connecting the semiconductor device with the deep via, and a first test device electrically connected with both the deep via and the interconnection layer, a second semiconductor chip over the first semiconductor chip, and a conductive bump interposed between the first and second semiconductor chips to electrically connect the first semiconductor chip with the second semiconductor chip.

According to embodiments, a semiconductor chip may include a semiconductor substrate including a semiconductor device, an insulating layer covering the semiconductor device over the semiconductor substrate, a deep via passing through the semiconductor substrate and the insulating layer, a top metal electrically connected with the semiconductor device, a first interconnection layer making direct contact with both the deep via and the top metal while covering an end surface of the deep via, a second interconnection layer making direct contact with the first interconnection layer while covering the first interconnection layer, and a test device electrically connected with the top metal to convert a signal input through the top metal.

As described above, according to embodiments, since the semiconductor chip and the semiconductor chip stacked package include a test device, the reliability of the semiconductor chip stacked package can be tested. In particular, the test device may be electrically connected to the deep via and the interconnection layer, so that shorting in the deep via and the interconnection layer can be tested. In addition, the test device may be electrically connected with the conductive bump, so that the connection between the semiconductor chips can be tested.

### DRAWINGS

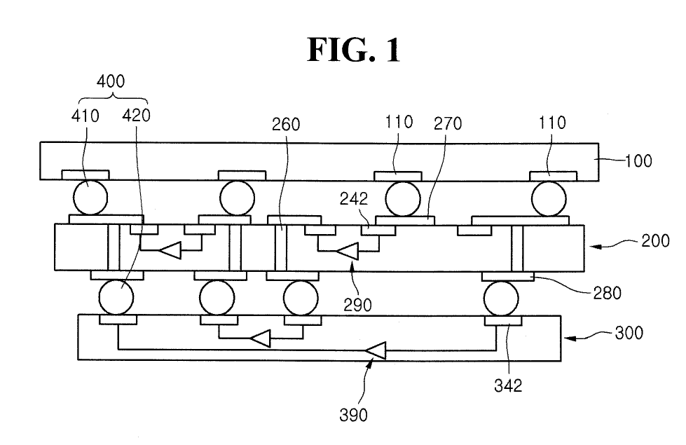

Example FIG. 1 is a view showing a semiconductor chip stacked package according to embodiments.

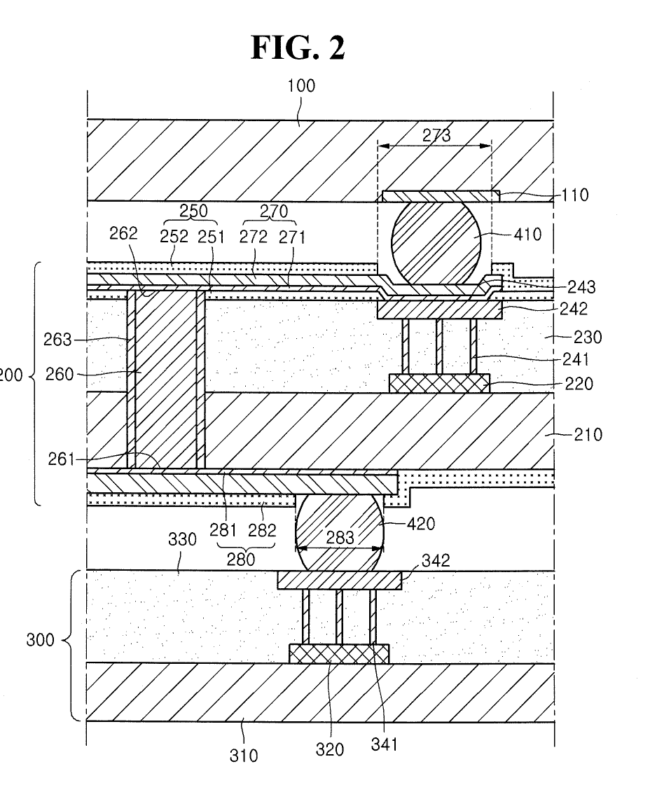

Example FIG. 2 is a sectional view showing the semiconductor chip stacked package.

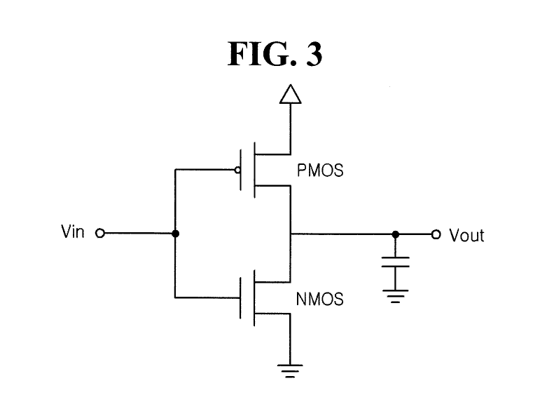

Example FIG. 3 is a circuit diagram showing first and second test devices.

### DESCRIPTION

Example FIG. 1 is a view showing a semiconductor chip stacked package according to embodiments, and example FIG. 2 is a sectional view showing the semiconductor chip stacked package. Example FIG. 3 is a circuit diagram showing first and second test devices.

Referring to example FIGS. 1 and 2, the semiconductor chip stacked package may include a printed circuit board 100, a first semiconductor chip 200, a second semiconductor chip 300, and conductive bumps 400.

The printed circuit board 100 may include a plurality of interconnections. The printed circuit board 100 may include connection pads 110 connected with the conductive bumps 400 through the interconnections.

The first semiconductor chip 200 may be stacked on the printed circuit board 100. For example, the first semiconductor chip 200 may be a memory chip. The first semiconductor chip 200 may include a first semiconductor substrate 210, a first semiconductor device 220, a first insulating layer 230, a first via 241, a first top metal 242, a protective layer 250, a deep via 260, a barrier metal 263, an upper interconnection layer (redistribution layer; RDL) 270, a lower interconnection layer 280, and a first test device 290.

The first semiconductor substrate 210 may be a silicon substrate. The first semiconductor substrate 210 may have a plate shape. The first semiconductor substrate 201 may have a predetermined thickness of about 40 μm to about 60 μm.

The first semiconductor device 220 may be provided over the first semiconductor substrate 210. The first semiconductor device 220 may be a transistor or a memory device.

The first insulating layer 230 may be provided over the first semiconductor substrate 210. The first insulating layer 230 may cover the first semiconductor device 220. The first insulating layer 230 may include undoped silicate glass (USG) or tetraethyl ortho silicate (TEOS).

The via 241 may pass through the insulating layer 230 so that the via 241 is electrically connected with the first semiconductor device 220. The first top metal 242 may be electrically connected with the first semiconductor device 220 through the first via 241. The first top metal 242 may have a flat top surface 243. The top surface 243 of the first top metal 242 may be exposed in line with a top surface of the first insulating layer 230. The first top metal 242 and the via 241 may include copper (Cu) and tungsten (W).

The protective layer 250 may include a first protective layer 251 formed over the first insulating layer 230 and a second protective layer 252 formed over the RDL 270. The first protective layer 251 may expose the top surface 243 of the first top metal 242. The protective layer 250 may include silicon oxide (SiO₂) or silicon nitride (Si₃N₄).

The deep via 260 may pass through the first semiconductor substrate 210, the first insulating layer 230, and the first protective layer 251. The deep via 260 may electrically connect the RDL 270 with the lower interconnection layer 280. A top surface 262 of the deep via 260 may make contact with the RDL 270, and a bottom surface 261 of the deep via 260 may make contact with the lower interconnection layer 280. The deep via 260 may have a column shape. In particular, the deep via 260 may have a cylindrical shape.

The barrier metal 263 may surround the deep via 260. The barrier metal 263 prevents a material filled in the deep via 260 from being diffused to the first semiconductor substrate 210 or the first insulating layer 230. The barrier metal 263 may include titanium (Ti), titanium nitride (TiN), titanium silicon nitride (TiSiN), tantalum (Ta), tantalum nitride (TaN), or tantalum silicon nitride (TaSiN).

The RDL 270 may be formed over the first protective layer 251. The RDL 270 may be connected to the first top metal 242 and the deep via 260. The RDL 270 may be electrically connected to the first semiconductor device 220 and the deep via 260. The RDL 270 may include a first interconnection layer 271 and a second interconnection layer 272. The RDL 270 includes first pad parts 273 exposed to an exterior, and making contact with the conductive bumps 400.

The first interconnection layer 271 may be formed over the first protective layer 251, and may cover both the top surface 262 of the deep via 260 and the top surface 243 of the top metal 242. The first interconnection layer 271 may make direct contact with both the deep via 260 and the first top metal 242. The first interconnection layer 271 may include Ti, TiN, TiSiN, Ta, TaN, or TaSiN.

The second interconnection layer 272 may be formed over the first interconnection layer 271. The second interconnection layer 272 may includes Cu, W, Al, or an alloy of Al. The first interconnection layer 271 performs an electrical and/or mechanical buffer function between the second interconnection layer 272 and the deep via 260, and between the second interconnection 272 and the top metal 242. In other words, the second interconnection layer 272 is connected to both the deep via 260 and the top metal 242 through the first interconnection layer 271.

The first interconnection layer 271 improves the electrical connection between the second interconnection layer 272 and the deep via 260. For example, when the deep via 260 includes Cu, and the second interconnection layer 272 includes Al, the direct connection between Cu and Al is difficult. In this case, the first interconnection layer 271 performs a buffer function.

In other words, the first interconnection layer 271 has a superior contact characteristic to that of the second interconnection layer 272. The second interconnection layer 272 has a superior electrical characteristic to that of the first interconnection layer 271.

For example, the first interconnection layer 271 may have a superior bonding strength to that of the second interconnection layer 272, and the second interconnection layer 272 may have a lower resistance than that of the first interconnection layer 271.

The lower interconnection layer 280 may be provided below the first semiconductor substrate 210. The lower interconnection layer 280 is electrically connected to the deep via 260. The lower interconnection layer 280 may include a third interconnection layer 281 and a fourth interconnection layer 282.

The third interconnection layer 281 may be provided below the first semiconductor substrate 210, and may cover the bottom surface 261 of the deep via 260. The third interconnection layer 281 may include Ti, TiN, TiSiN, Ta, TaN, or TaSiN. The fourth interconnection layer 282 may be formed below the third interconnection layer 281. The fourth interconnection layer 282 may include Al or alloy of Al. The lower interconnection layer 280 includes second pad parts 283 exposed to an exterior, and making contact with the conductive bumps 400.

The first test device 290 may be formed in the first insulating layer 230 or over the first semiconductor substrate 210. The first test device 290 may test for shorting in the first top metal 242, the RDL 270, the lower interconnection layer 280, and/or the deep via 260.

The first test device 290 may be electrically connected to the first top metal 242. Accordingly, the first test device 290 may be electrically connected to the first top metal 242, the RDL 270, the lower interconnection layer 280, and the deep via 260. The first test device 290 may be an inverter to convert an input digital signal. When a signal ‘0’ is input to the first test device 290, the first test device 290 may output a signal ‘1’. When a signal ‘1’ is input to the first test device 290, the first test device 290 may output a signal ‘0’. A plurality of first top metals 242 may be employed, and the first test device 290 may connect the different first top metals 242 to each other.

Referring to example FIG. 3, the first test device 290 may be a CMOS inverter having an NMOS transistor and a PMOS transistor. A signal input into the CMOS inverter through an input terminal Vin is converted and then output through an output terminal Vout.

The second semiconductor chip 300 may be provided below the first semiconductor chip 200. For example, the second semiconductor chip 300 may be a logic chip including logic devices. The second semiconductor chip 300 may include a second semiconductor substrate 310, a second semiconductor device 320, a second insulating layer 330, a second via 341, a second top metal 342, and a second test device 390. The second semiconductor substrate 310 may include an amorphous silicon substrate and have a plate shape.

The second semiconductor device 320 may be formed over the second semiconductor substrate 310. The second semiconductor device 320 may include a transistor. For example, the second semiconductor device 320 may include logic devices for logic operations.

The second insulating layer 330 may be formed over the second semiconductor substrate 310. The second insulating layer 330 may cover the second semiconductor device 320. The second via 341 may pass through the second insulating layer 330, and may be electrically connected with the second semiconductor device 320.

The second top metal 342 may be connected with the second via 341, and a top surface of the second top metal 342 may be exposed in a line with a top surface of the second insulating layer 330. The second via 341 and the second top metal 342 may include Cu, W, or Al.

The second test device 390 may be formed over the second semiconductor substrate 310, and electrically connected with the second top metal 342. The second test device 390 may be an inverter to receive an input signal. The second test device 390 may be identical to the first test device 290. A plurality of second top metals 342 may be employed, and the second test device 390 may connect two different top metals 342 to each other.

The conductive bump 400 is a conductor. The conductive bump 400 may include Ag or Cu. The conductive bump 400 may include a first conductive bump 410 and a second conductive bump 420.

The first conductive bump 410 may be interposed between the printed circuit board 100 and the first semiconductor chip 200 to electrically connect the printed circuit board 100 to the first semiconductor chip 200. The first conductive bump 410 may make contact with the first pad part 273 and the contact pad 110. The first conductive bump 410 may be electrically connected to the connection pad 110 and the RDL 270.

The second conductive bump 420 may be interposed between the first semiconductor chip 200 and the second semiconductor chip 300. The second conductive bump 420 may electrically connect the first semiconductor chip 200 with the second semiconductor chip 300. The second conductive bump 420 may make contact with the second top metal 342 and the second pad part 283. In addition, the second conductive bump 420 may be electrically connected to both the lower interconnection layer 280 and the second top metal 342.

In other words, the printed circuit board 100 may be electrically connected to the second semiconductor chip 300 through the first conductive bump 410, the RDL 270, the top via 260, the lower interconnection layer 280, and the second conductive bump 420. Accordingly, a signal from the printed circuit board 100 can be applied to the first and second semiconductor chips 200 and 300.

In this case, the reliability of the semiconductor chip stacked package according to embodiments can be checked by the first and second test devices 290 and 390. For example, a digital signal applied through the printed circuit board 100 may be applied to the first test device 290 through the first conductive bump 410, the RDL 270, and the first top metal 242. After the digital signal has been converted in the first test device 290, the digital signal can be output through another location in the first top metal 242 and the top via 260.

In this case, the digital signal that has been output may be detected and checked if the digital signal has been converted, so that shorting in the first conductive bump 410, the RDL 270, the first top metal 242, and the deep via 260 may be detected.

In addition, the digital signal from the printed circuit board 100 may be applied to the second test device 390 through the first conductive bump 410, the RDL 270, the deep via 260, the lower interconnection layer 280, the second conductive bump 420, and the second top metal 342. After the digital signal has been converted by the second test device 390, the digital signal can be output through the second metal 342 and the second conductive bump 420.

In this case, the digital signal that has been output may be detected and checked if the digital signal has been converted, so that shorting in the first conductive bump 410, the RDL 270, the deep via 260, the lower interconnection layer 280, the second conductive bump 420, and the second top metal 342 can be recognized.

According to embodiments, the digital signal may be input into the semiconductor chip stacked package and the conversion of an output digital signal may be checked, so that the reliability of the semiconductor chip stacked package can be tested. In addition, according to embodiments, the semiconductor chip stacked package can determine shorting in the first top metal 242, the second top metal 342, the deep via 260, the conductive bump 400, the RDL 270, and the lower interconnection layer 280.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a semiconductor substrate formed with a semiconductor device;
an insulating layer over the semiconductor substrate;
a deep via passing through the semiconductor substrate and the insulating layer;
an interconnection layer electrically connecting the semiconductor device with the deep via; and
a test device electrically connected with both the deep via and the interconnection layer.

2. The apparatus of claim 1, wherein the test device is an inverter which converts a digital signal input through the deep via.

3. The apparatus of claim 1, wherein the test device is an inverter which converts a digital signal input through the interconnection layer.

4. The apparatus of claim 1, wherein the interconnection layer includes:
a first interconnection layer covering one end surface of the deep via; and
a second interconnection layer covering the first interconnection layer.

5. The apparatus of claim 4, wherein the first interconnection layer includes at least one chosen from the group consisting of titanium, titanium nitride, titanium silicon nitride, tantalum, tantalum nitride, and tantalum silicon nitride.

6. The apparatus of claim 4, including a top metal making contact with the first interconnection layer, wherein the test device is electrically connected with the top metal.

7. The apparatus of claim 6, including a protective layer between the first top metal and the interconnection layer.

8. The apparatus of claim 1, including a barrier metal surrounding the deep via.

9. An apparatus comprising:
a first semiconductor chip, which includes a semiconductor substrate formed with a semiconductor device, an insulating layer over the semiconductor substrate, a deep via passing through the semiconductor substrate and the insulating layer, an interconnection layer electrically connecting the semiconductor device with the deep via, and a first test device electrically connected with both the deep via and the interconnection layer;
a second semiconductor chip over the first semiconductor chip; and
a conductive bump interposed between the first and second semiconductor chips to electrically connect the first semiconductor chip with the second semiconductor chip.

10. The apparatus of claim 9, wherein the first semiconductor chip includes a pad connected with the interconnection layer, and the bump makes contact with the pad.

11. The apparatus of claim 9, wherein the second semiconductor chip includes a top metal electrically connected with the bump.

12. The apparatus of claim 11, wherein the second semiconductor chip includes a second test device electrically connected with the top metal.

13. The apparatus of claim 12, wherein the first and second test devices convert an input signal.

14. The apparatus of claim 12, wherein the first and second test devices are inverters.

15. The apparatus of claim 9, including a barrier metal surrounding the deep via.

16. An apparatus comprising:
a semiconductor substrate including a semiconductor device;
an insulating layer covering the semiconductor device over the semiconductor substrate;
a deep via passing through the semiconductor substrate and the insulating layer;
a top metal electrically connected with the semiconductor device;
a first interconnection layer making direct contact with both the deep via and the top metal while covering an end surface of the deep via;
a second interconnection layer making direct contact with the first interconnection layer while covering the first interconnection layer; and
a test device electrically connected with the top metal to convert a signal input through the top metal.

17. The apparatus of claim 16, wherein the first interconnection layer includes one selected from the group consisting of titanium, titanium nitride, titanium silicon nitride, tantalum, tantalum nitride, and tantalum silicon nitride.

18. The apparatus of claim 16, wherein the second interconnection layer includes one selected from the group consisting of aluminum, copper and tungsten.

19. The apparatus of claim 16, wherein the test device includes first and second transistors.

20. The apparatus of claim 16, wherein the test device is an inverter.
